(19) United States
(12) Patent Application Publication
(10) Pub. No.: US 2013/0021750 A1
(43) Pub. Date: Jan. 24, 2013

(54) ELECTRONIC DEVICE THERMAL MANAGEMENT

(71) Applicant: Mark David Senatori, The Woodlands, TX (US)

(72) Inventor: Mark David Senatori, The Woodlands, TX (US)

(73) Assignee: Hewlett-Packard Development Company, LP., Houston, TX (US)

(21) Appl. No.: 13/637,651

(22) PCT Filed: Jul. 8, 2010
(86) PCT No.: PCT/US10/41385

§ 371 Date: Sep. 27, 2012

(51) Int. Cl. H05K 7/20; F28F 27/00

(52) U.S. Cl. 361/695; 165/11.1; 361/688; 361/690

(57) ABSTRACT

A thermal management system for an electronic device comprising thermal management controller configured to adjust a temperature level of at least a portion of an interior of a housing of the electronic device based on a signal indicative of a change in an electrostatic field exterior to the housing of the electronic device.

### BACKGROUND

An electronic device, such as a notebook computer, often includes a housing to support an electronic component, such as a processor, and a cooling mechanism, such as a fan. The operation of the electronic component typically increases the temperature of the housing and the cooling mechanism is activated to help reduce the temperature of the housing.

### BRIEF DESCRIPTION OF THE DRAWINGS

For a detailed description of example embodiments, reference will now be made to the accompanying drawings in which:

FIG. 1 is a diagram illustrating a perspective view of an electronic device employing an embodiment of a thermal management system, in accordance with at least some illustrative embodiments;

FIG. 2 is a diagram illustrating a perspective view of another embodiment of the electronic device employing the thermal management system of FIG. 1;

FIG. 3 is a block diagram of the electronic device of FIG. 1, constructed in accordance with at least some illustrative embodiments; and

FIG. 4 is a flow diagram illustrating a method of thermal management, constructed in accordance with at least some illustrative embodiments.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to he exemplary of that embodiment, and not intended to intimate that the scope of the disclosure, including the claims, is limited to that embodiment.

The operation of an electronic device may increase the temperature of the interior and exterior of the device housing. A user may place the electronic device on their lap which may make the user uncomfortable because of the increased temperature of the bottom surface of the housing. To help address this situation, in one embodiment, disclosed is a thermal management system that can help reduce the temperature of the housing by detecting the presence of a thermal generating object being proximate or dose to the device and adjusting the temperature of the device accordingly. In one embodiment, the electronic device can adjust a temperature level of at least a portion of an interior of a device housing based on a signal indicative of a change in an electrostatic field exterior to the device housing. The signal can be generated by a thermal generating object, such as a human being, entering the electrostatic field. The device is configured to adjust the performance level of at least one electronic component and/or fan disposed in the interior of the housing based on the signal. Such adjustments may help decrease the temperature of the housing thereby helping to make it a more comfortable experience for the user.

For example, the electronic device can be a notebook computer having a capacitive proximity sensor configured to generate an electrostatic field and detect a change in the electrostatic field caused by a user's body being near the notebook and automatically correct for this situation. The sensor can be configured to detect the difference between a thermal generating object, such as a lap of a human being, and a non-Thermal generating object such as a surface of a table. When the computer is nearing or being placed against a part of a user's body, such as their lap, the capacitive proximity sensor detects this event and communicates this information to the device. The device can be configured to respond by adjusting thermal control components of the computer such as increase fan speed, adjust performance of the processor, open or close vents, adjust a baffle system, and the like.

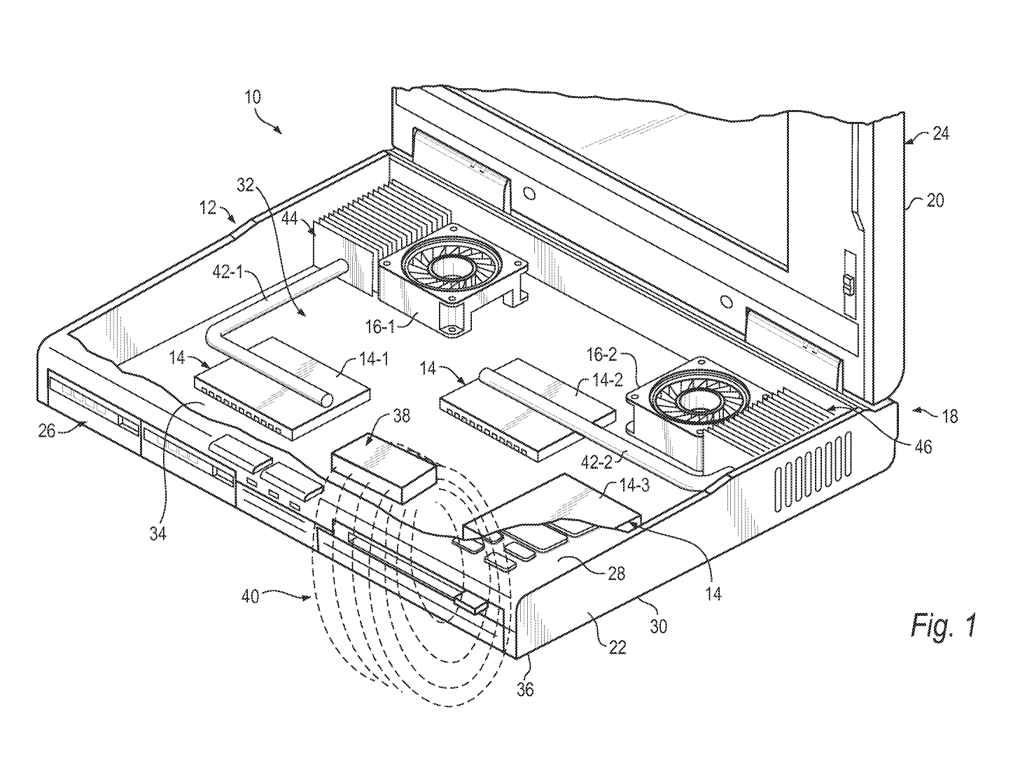

Various embodiments and the advantages thereof are best understood by referring to FIGS. 1-4 like numerals being used for like and corresponding parts of the various drawings.

FIG. 1 shows an electronic device 10 having a thermal management system 12 in accordance with an embodiment. FIG. 1 shows thermal management system 12 configured to dynamically control the use of computer components 14 and/or cooling fans 16-1 and/or 16-2 of electronic device 10 in response to sensor 38 detecting changes in an electrostatic field 40 external or exterior to electronic device 10 caused by the presence of a thermal generating object (not shown) such as a human being entering the field. In the embodiment illustrated in FIG. 1, electronic device 10 comprises a laptop or notebook computer 18; however, it should be understood that electronic device 10 may comprise any type of electronic device such as, but not limited to, a tablet personal computer, a personal digital assistant, a desktop computer, a cellular telephone, a gaming device, an entertainment device or any other type of portable or non-portable electronic device. In the embodiment illustrated in FIG. 1, electronic device 10 comprises a display member 20 rotatably coupled to a base member 22. Display member 20 and base member 22 each comprise a housing 24 and 26, respectively, formed having a number of walls. For example, housing 26 comprises an interior space 32 and a top wall defining a working surface 28 and a bottom wall 30 with an interior surface 34 and an exterior surface 36.

In the embodiment illustrated in FIG. 1, thermal management system 12 comprises sensor 38 disposed on the interior surface 34 of wall 30 of housing 26. The sensor 38 is configured to generate an electrostatic field 40 that extends to exterior surface 36 of wall 30. The sensor 38 can also detect the presence of a thermal generating object such as a human being entering the field 40 at the exterior surface 36 of wall 30. For example, in FIG. 1, thermal management system 12 comprises a single sensor 38, however it should be understood that a greater number of sensors 38 may be utilized. In the embodiment illustrated in FIG. 1, sensor 38 is embedded within and/or are coupled directly to the interior surface 34 of the bottom wall 30 and is disposed generally adjacent to components 14; however, it should be understood that sensor 38 may be otherwise located and embedded within and/or coupled to any other wall of base member 22 and/or at any other location within base member 22. Components 14 may comprise a variety of different types of devices used in the operation of electronic device 10 that may generate thermal loads within housing 26, thereby increasing the temperature within housing 26 including bottom wail 30. In the embodiment illustrated in FIG. 1, components 14 comprise a processor 14-1, a graphics chip 14-2, and a wireless radio module 14-3, thermally coupled via heat transport elements 42-1 and 42-2 to a pair of heat exchangers 44 and 46, respectively, to dissipate heat generated by processor 14-1 and graphics chip 14-2. In the embodiment illustrated in FIG. 1, cooling fans 16-1 and/or 16-2 are configured to generate airflow through housing 26 to dissipate heat generated by components 14 using heat exchangers 44 and/or 46. In operation, sensor 38 monitor for changes in electrostatic field 40 external to the housing indicative of a thermal generating object such as a human being and regulates the heat generated within housing 26 and thus the temperature of bottom wall 30.

In operation, thermal management system 12 is configured to dynamically adjust a temperature level within housing 26, thereby adjusting a temperature of wall 30 of electronic device 10, based on a signal indicative of a change in electrostatic field 40 exterior to the housing. For example, if the sensor 38 detects a change in the field caused by the presence of a thermal generating object, such as human being, entering the field, the thermal management system 12 is operable to adjust one or more components 14 and/or the operation and/or speed of the one or more cooling fans 16-1 and/or 16-2 within electronic device 10 to reduce the temperature within electronic device 10 and thus wall 30. In this manner, the temperature of bottom wall 30 is adjusted to be above a predetermined temperature/threshold making it comfortable to rest bottom wall 30 of housing 26 on a user's lap,

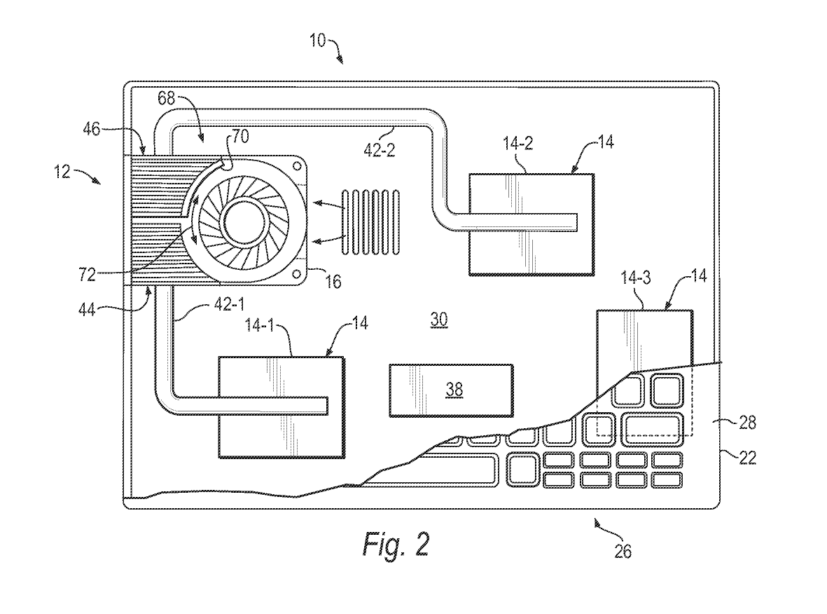

FIG. 2 is a diagram illustrating a perspective view of another embodiment of electronic device 10 employing thermal management system 12 of FIG. 1. In the embodiment illustrated in FIG. 2, thermal management system 12 is configured to adjust a baffle system 68 to direct and/or re-direct an airflow generated by cooling fan 16. For example, in the embodiment illustrated in FIG. 2, heat exchangers 44 and 46 are configured adjacent to cooling fan 16 to receive cooling air. A baffle 70 is movably positionable within cooling fan 16 in the directions of arrow 72 to direct cooling air generated by cooling fan 16 to one or both of heat exchangers 44 and 46. For example, in the embodiment illustrated in FIG. 2, in the event sensor 38 detects a change in the electrostatic field 40 caused by a thermal generating object, thermal management system 12 adjusts the position of baffle 70 to at least partially block the airflow through exchanger 46 and otherwise divert all or a portion of the airflow toward exchanger 44 to increase the cooling rate of component 14-1.

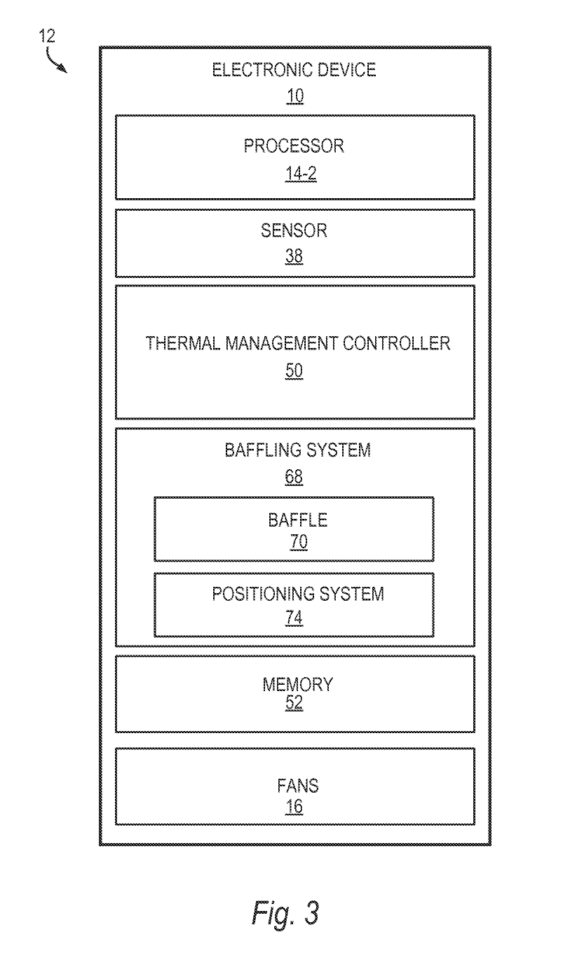

FIG. 3 is a block diagram illustrating electronic device 10 of FIGS. 1 and 2. In FIG. 3, thermal management system 12 comprises sensor 38 and a thermal management controller 50 configured to receive inputs from the sensor. In the embodiment illustrated in FIG. 3, electronic device 10 comprises processor 14-2, sensor 38, baffling system 68, memory 52 and one or more cooling fans 16. In the embodiment illustrated in FIG. 3, memory 54 can store information related to the operation of device 10. For example, controller 50 can be configured to store and access information related to calibration of sensor 38 to allow it to detect the difference between a thermal generating object, such as a human being, and a non-thermal generating object such as the surface of a table. The controller 50 can be configured to store and access information in memory 52 related to the temperature of the housing which can be used by the controller to adjust the components of the device to decrease the temperature of the housing thereby providing a comfortable experience for the user.

In one embodiment, sensor 38 can be configured to generate electrostatic field 40 that extends to the exterior 36 of bottom wall 30 of housing 26. The sensor 38 can be configured to detect changes in electrostatic field 40 caused by objects having certain properties entering the field. The sensor 38 can be calibrated to generate a signal when particular objects enter the field and disregard or ignore other objects. For example, sensor 38 can be calibrated to generate a signal when a thermal generating object, such as a portion of a human being such as a person's lap, enters the field. It can also be calibrated to ignore or disregard a non-thermal generating object, such as a surface of a desk, when it enters the field. Therefore, sensor 38 can be configured to detect when electronic device 10 is placed on a user's lap and ignore when the device is placed onto a surface of a table. The sensor 38 can communicate this information to controller 50 which can then adjust the temperature of the housing of device 10 accordingly including lowering the temperature of housing of the device.

For example, sensor 38 can be a capacitive proximity sensor having a sensing surface formed by two concentrically shaped metal electrodes of an unwound capacitor. When an object nears the sensing surface it enters the electrostatic field of the electrodes and changes the capacitance in an oscillator circuit. As a result, the oscillator begins oscillating. A trigger circuit reads the oscillators' amplitude and when it reaches a specific level the output state of the sensor changes. As the object moves away from the sensor, the oscillator's amplitude decreases, switching the sensor output back to its original state. Standard objects can be specified for the sensor. The sensor can be based on the dielectric constant of the object. In one example, the sensor can be selected to generate a signal for dielectric constant of an object comprising thermal generating properties such as a human being and not generate a signal for dielectric constant of a non-thermal generating object such as a surface of a table. Although sensor 38 is described as generating an electrostatic field and detecting changes in the field, other sensors capable of detecting the presence of an object can be used. For example, sensor 38 can be a device capable of generating ultrasonic field and detecting changes in the field based on an object entering the field.

In FIG. 3, thermal controller 50 may comprise hardware, software, firmware or a combination of hardware, software and firmware. In operation, thermal controller 50 can receive a signal from sensor 38 indicative of a change in electrostatic field 40 at the exterior 36 to bottom wall 30 of housing 26. The controller 50 can check the signal to determine whether it represents a change caused by a thermal generating object or a non-thermal generating object. The controller 50 can adjust a temperature level of at least a portion of the interior 32 of housing 26 based on the signal. For example, in the event sensor 38 detects the presence of a thermal generating object within field 40 at the exterior of bottom wall 30 (FIG, 1), thermal management controller 50 can generate a command to adjust the performance of one or more components 14 (e.g., adjust data transfer rates, turn off and/or reduce a performance level of radio module 14-3, adjust a clock frequency of processor 14-1, adjust baffling system 68 and/or adjust the speed of cooling fans 16-1 and/or 16-2.

In another embodiment, thermal controller 50 can be configured to collect data from sensor 38 and store it in memory 52 for further processing. The controller 50 can compare the collected data to predefined data representing a thermal generating object to determine whether a thermal generating object caused a change in the electrostatic field. For example, in the event sensor 38 detects a change in the field at the bottom wall 30 (FIG. 1), controller 50 analyzes this information and, if it represents a thermal generating object, the controller generates a command to adjust the performance of one or more components as explained above. Therefore, controller 50 can adjust the temperature of housing 26 based on the presence of a thermal generating object proximate or near bottom wall 30 of the housing of the device.

In another embodiment, thermal management system 12 can be configured to include thermal sensors (not shown) to monitor temperature level(s) within housing 26. The thermal controller 50 can collect temperature data from the thermal sensor and store it as temperature detection data in memory 52 for further processing. The controller 50 can compare the temperature detection data to a temperature threshold data to determine whether temperature detection data is above a predetermined temperature threshold value (e.g., whether the detected temperature is above a predetermined temperature) stored as temperature threshold data. For example, in the event the thermal sensor detects a temperature level of bottom wall 30 (FIG. 1) greater than the value stored as temperature threshold data (e.g., the highest acceptable temperature of bottom wall 30), thermal management controller 50 can generate a command to adjust the performance of one or more components 14, adjust baffling system 68 and/or adjust the speed of cooling fans 16. The controller 50 can adjust the temperature of the housing based on a combination of temperature data from a thermal sensor and data representing a thermal generating object from sensor 38.

In the embodiment illustrated in FIG. 3, baffling system 68 comprises baffle 70 and a positioning system 74 for variably positioning baffle 70 to direct and/or redirect cooling air flow through electronic device 10. According to some embodiments, positioning system 74 may comprise an electric motor to drive a worm gear and/or any other mechanism to variably position baffle 70 within electronic device 10; however, it should be understood that other methods of variably positioning baffle 70 are available.

In the embodiment illustrated in FIGS. 1-3, thermal management controller 50 is configured to dynamically adjust operation of electronic device 10 such that the temperature within housing 26 reduces and/or substantially eliminates the likelihood of wall bottom 30 warming above a temperature that may make it uncomfortable to have the device on a user's lap. For example, in the event sensor 38 detects a change in the electrostatic field 40 caused by the bottom wall of the device being placed on or approaching a user's lap, controller 50 sends a signal to increase the speed of fan 16-1 to increase the cooling rate of processor 14-1 via increased thermal dissipation within heat exchanger 46. Additionally and/or alternatively, thermal management controller 50 can optionally send a signal to control (e.g., reduce) the performance of processor 14-1.

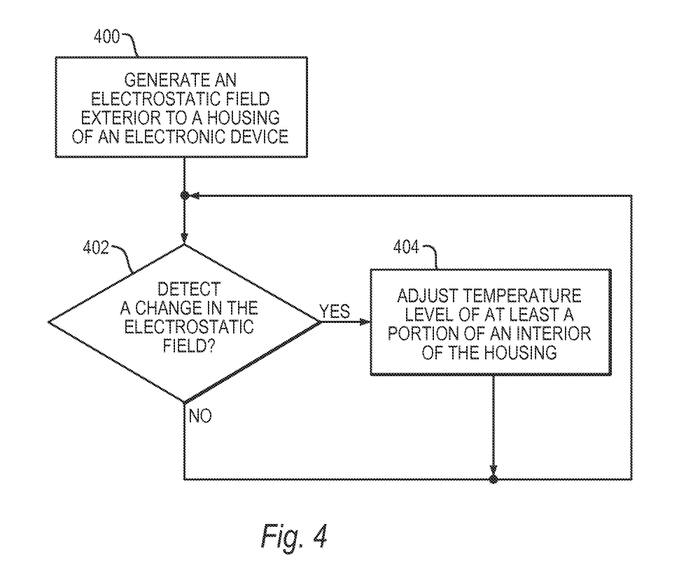

FIG. 4 shows a flow diagram of a thermal management method in accordance with various embodiments. Though depicted sequentially as a matter of convenience, at least some of the actions shown can be performed in a different order and/or performed in parallel. Additionally, some embodiments may perform only some of the actions shown. In the embodiment illustrated in FIG. 4, the method begins at block 400 where sensor 38 generates an electrostatic field 40 that extends to the exterior 36 of bottom wall 30 of the housing 26. At block 402, sensor 38 checks for a change in electrostatic field 40 and sends the signal to thermal management controller 50 for further processing. If controller 50 determines that the change is caused by a thermal generating object entering the field 40, then the method proceeds to block 404, where controller 50 adjusts performance level of component 14 and/or adjust the operating of cooling fans 16 to enable comfortable use of electronic device 10. For example, controller 50 can adjust the operation and/performance of components to help reduce the temperature of housing and thereby help make bottom wall 30 of the housing of the device comfortable when it is placed on the lap of a user. In another example, controller 50 can adjust the components to temperature levels below a predefined temperature to help make bottom wall 30 of the housing of the device comfortable when it is placed on the lap of a user. The method proceeds to block 402 wherein sensor 38 continues to check for changes in electrostatic field 40. In the event sensor 38 does not detect change in the electrostatic field 40, the method proceeds to block 402 wherein the sensor continues checking for changes in the electrostatic field.

Thus, embodiments of thermal management system 12 may help regulate the temperature of electronic device 10 (e.g. housing 24 and/or 26) based on the presence of a thermal generating object proximate the bottom surface of the device. In particular, embodiments of thermal management system 12 may help regulate the temperature of electronic device 10 by automatically adjusting components 14 and/or, one or more cooling fans 16 and/or a baffling system 68 therein.

The thermal management system in some embodiments may exhibit advantages. For example, the system can detect the presence of a user approaching or being near the device and then adjust the temperature of the device before the user makes actual physical contact with the device. In this manner, the device CaO reduce any lag which would be experienced by waiting for actual contact with the device or measurement of the temperature of the device housing. Furthermore, the system can rely on a change in an electrostatic field to detect the presence of a person without requiring mechanical components or physical contact with the person which may help reduce the complexity and increase the reliability of the system.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A thermal management system for an electronic device comprising:
a thermal management controller configured to adjust a temperature level of at least a portion of an interior of a housing of the electronic device based on a signal indicative of a change in an electrostatic field exterior to the housing of the electronic device.

2. The thermal management system of claim 1, wherein the device is configured to generate the electrostatic field to the exterior of the housing.

3. The thermal management system of claim 1, wherein the device is configured to detect a thermal generating object located within the electrostatic field at the exterior of the housing.

4. The thermal management system of claim 1, wherein the signal indicative of a change in an electrostatic field is generated by a thermal generating object located within the electrostatic field at the exterior of the housing.

5. The thermal management system of claim 1, wherein the thermal management controller is further configured to adjust performance level of at least one electronic component disposed in the interior of the housing based on the signal indicative of a change in the electrostatic field exterior to the housing.

6. The thermal management system of claim 1, wherein the thermal management controller is further configured to adjust operation of at least one fan disposed in the interior of the housing based on the signal indicative of a change in the electrostatic field exterior to the housing.

7. The thermal management system of claim 1, wherein the thermal management controller is further configured to adjust operation of a baffling system disposed in the interior of the housing based on the signal indicative of a change in the electrostatic field exterior to the housing.

8. An electronic device comprising:
a display member; and
a base member comprising a housing configured to support a thermal management controller configured to adjust a temperature level of at least a portion of an interior of the housing based on a signal indicative of a change in an electrostatic field exterior to the housing.

9. The electronic device of claim 8, wherein the device is configured to generate the electrostatic field to the exterior of the housing.

10. The electronic device of claim 8, wherein the device is configured to detect a thermal generating object located within the electrostatic field at the exterior of the housing.

11. The electronic device of claim 8, wherein the signal indicative of a change in an electrostatic field is generated by a thermal generating object located within the electrostatic field at the exterior of the housing.

12. The electronic device of claim 8, wherein the thermal management controller is further configured to adjust performance level of at least one electronic component disposed in the interior of the housing based on the signal indicative of a change in the electrostatic field exterior to the housing.

13. The electronic device of claim 8, wherein the thermal management controller is further configured to adjust operation of at least one fan disposed in the interior of the housing based on the signal indicative of a change in the electrostatic field exterior to the housing.

14. The electronic device of claim 8, wherein the thermal management controller is further configured to adjust operation of baffling system disposed in the interior of the housing based on the signal indicative of a change in the electrostatic field exterior to the housing.

15. A thermal management method comprising:
detecting a change in an electrostatic field exterior to a housing of an electronic device; and
adjusting a temperature level of at least a portion of an interior of a housing of the electronic device based on the detected change in the electrostatic field.

16. The thermal management method of claim 15, wherein detecting a change in the electrostatic is caused by a thermal generating object located within the electrostatic field at the exterior of the housing.

17. The thermal management method of claim 15, further comprising generating the electrostatic field exterior to the housing.

18. The thermal management method of claim 15, further comprising adjusting performance level of at least one electronic component disposed in the interior of the housing based on the detected change in the electrostatic field.

19. The thermal management method of claim 15, further comprising adjusting operation of at least one fan disposed in the interior of the housing based on the detected change in the electrostatic field.

20. The thermal management method of claim 15, further comprising adjusting operation of a baffling system disposed in the interior of the housing based on the detected change in the electrostatic field.
